(19) United States
(12) Patent Application Publication
(10) Pub. No.: US 2026/0075745 A1
(43) Pub. Date: Mar. 12, 2026

(54) HEAT-REJECTING MEDIA WITH MIXED MATERIALS

(71) Applicant: Dell Products L.P., Round Rock, TX (US)

(72) Inventors: Qinghong HE, Austin, TX (US); Travis NORTH, Cedar Park, TX (US)

(73) Assignee: Dell Products L.P., Round Rock, TX (US)

(21) Appl. No.: 18/882,486

(22) Filed: Sep. 11, 2024

(51) Int. Cl. H05K 7/20; G06F 1/20

(52) U.S. Cl. CPC H05K 7/20136; G06F 1/206

(57) ABSTRACT

An information handling system may include an information handling resource, an air mover configured to drive airflow within the information handling system, and heat-rejecting media thermally coupled to the information handling resource. The heat-rejecting media may include a first portion configured to be located within the airflow and comprising a first thermally-conductive material having a first thermal conductivity and a second portion configured to be located within the airflow and comprising a second thermally-conductive material having a second thermal conductivity substantially different from the first thermal conductivity.

### TECHNICAL FIELD

The present disclosure relates in general to information handling systems, and more particularly to cooling of information handling system components using a heat-rejecting media made of mixed materials, for example copper and aluminum, in conjunction with airflow-based cooling.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Further, heat-rejecting media such as heat pipes, heat spreaders, and heat sinks are often thermally coupled to heat-generating devices of information handling systems and placed in the airflow path of an air mover, to also aid in cooling of an information handling system and its components. Such heat-rejecting media may be thermally-coupled to one or more heat—generating devices of an information handling system, and configured to transfer heat from such heat-generating devices. Further, such heat-rejecting media may include surfaces located within the airflow of air movers, so that heat may further be transferred from heat-rejecting media to the cooling airflow.

Copper is often chosen as a material for use in heat-rejecting media, due to its high thermal conductivity. For instance, copper is known to have twice the thermal conductivity of aluminum. However, copper is approximately 3.3 times more dense than aluminum, meaning that for similarly-sized form factors of copper and aluminum, copper is 3.3 times heavier. In addition, copper is often three to four times costlier than aluminum per unit of mass. Thus, aluminum may sometimes be preferable to use in heat-rejecting media due to lower costs and weight, even at the expense of lower thermal performance.

### SUMMARY

In accordance with the teachings of the present disclosure, the disadvantages and problems associated with traditional approaches to cooling information handling system components may be substantially reduced or eliminated.

In accordance with embodiments of the present disclosure, an information handling system may include an information handling resource, an air mover configured to drive airflow within the information handling system, and heat-rejecting media thermally coupled to the information handling resource. The heat-rejecting media may include a first portion configured to be located within the airflow and comprising a first thermally-conductive material having a first thermal conductivity and a second portion configured to be located within the airflow and comprising a second thermally-conductive material having a second thermal conductivity substantially different from the first thermal conductivity.

In accordance with these and other embodiments of the present disclosure, heat-rejecting media configured to thermally couple to an information handling resource may include a first portion configured to be located within an airflow and comprising a first thermally-conductive material having a first thermal conductivity and a second portion configured to be located within the airflow and comprising a second thermally-conductive material having a second thermal conductivity substantially different from the first thermal conductivity.

In accordance with these and other embodiments of the present disclosure, a method may include configuring a first portion of heat-rejecting media within an airflow, wherein the first portion comprises a first thermally-conductive material having a first thermal conductivity, and wherein heat-rejecting media is configured to thermally couple to an information handling resource and configuring a second portion of the heat-rejecting media within the airflow, wherein the second portion comprises a second thermally-conductive material having a second thermal conductivity substantially different from the first thermal conductivity.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2 illustrates a top-down plan view of selected components of an example information handling system, in accordance with embodiments of the present disclosure;

FIG. 3 illustrates an isometric perspective view of example heat-rejecting media having fin stacks in fluid communication with air movers, in accordance with embodiments of the present disclosure; and

FIG. 4 illustrates an isometric perspective view of another example heat-rejecting media, in accordance with embodiments of the present disclosure.

### DETAILED DESCRIPTION

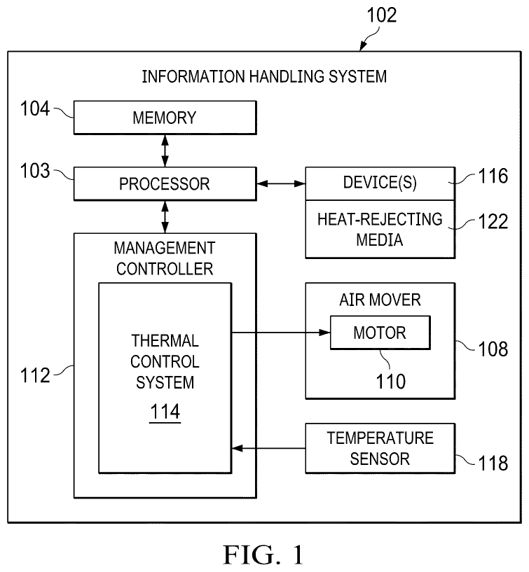

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of selected components of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104 communicatively coupled to processor 103, an air mover 108, a management controller 112, one or more devices 116 communicatively coupled to processor 103, a temperature sensor 118, and heat-rejecting media 122 thermally coupled to device(s) 116.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Air mover 108 may include any mechanical or electro-mechanical system, apparatus, or device operable to move air and/or other gases in order to cool information handling resources of information handling system 102. In some embodiments, air mover 108 may comprise a fan (e.g., a rotating arrangement of vanes or blades which act on the air). In other embodiments, air mover 108 may comprise a blower (e.g., a centrifugal fan that employs rotating impellers to accelerate air received at its intake and change the direction of the airflow). In these and other embodiments, rotating and other moving components of air mover 108 may be driven by a motor 110. The rotational speed of motor 110 may be controlled by an air mover control signal (e.g., a pulse-width modulation signal) communicated from thermal control system 114 of management controller 112. In operation, air mover 108 may cool information handling resources of information handling system 102 by drawing cool air into an enclosure housing the information handling resources from outside the chassis, expelling warm air from inside the enclosure to the outside of such enclosure, and/or moving air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources.

Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 118) and based on such one or more signals, calculate an air mover driving signal (e.g., a pulse-width modulation signal) to maintain an appropriate level of cooling, increase cooling, or decrease cooling, as appropriate, and communicate such air mover driving signal to air mover 108. Thermal control for air mover 108 by thermal control system 114 may be performed in any suitable manner, for example, as described in U.S. Pat. No. 10,146,190 entitled “Systems and Methods for Providing Controller Response Stability in a Closed-Loop System.”

In addition, thermal control system 114 may also be configured to maintain acoustic limits and/or maintain acoustic preferences for sound generated by air mover 108, for example, as described in U.S. patent application Ser. No. 16/852,118, filed Apr. 17, 2020, and entitled “Systems and Methods for Acoustic Limits of Thermal Control System in an Information Handling System,” which is incorporated by reference herein in its entirety.

In some embodiments, thermal control system 114 may include a program of instructions (e.g., software, firmware) configured to, when executed by a processor or controller integral to management controller 112, carry out the functionality of thermal control system 114.

A device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

Temperature sensor 118 may comprise any system, device, or apparatus (e.g., a thermometer, thermistor, etc.) configured to communicate a signal to thermal control system 114 indicative of a temperature within information handling system 102.

Heat-rejecting media 122 may include any system, device, or apparatus configured to transfer heat from an information handling resource (e.g., device(s) 116, as shown in FIG. 1), thus reducing a temperature of the information handling resource. For example, heat-rejecting media 122 may include one or more solids thermally coupled to the information handling resource (e.g., heat pipe, heat spreader, heatsink, finstack, etc.) such that heat generated by the information handling resource is transferred from the information handling resource. Further, heat-rejecting media 122 may be arranged to be located within the airflow path of airflow generated by air mover 108, such that heat transferred to heat-rejecting media 122 from device 116 may further be transferred to such airflow. Although, for purposes of clarity and exposition, heat-rejecting media 122 is shown as being thermally coupled to device(s) 116, it is understood that heat-rejecting media 122 may also be thermally coupled to other information handling resources (e.g., processor 103 and/or memory 104) of information handling system 102 in addition to or in lieu of being thermally coupled to device 116.

In addition to processor 103, memory 104, air mover 108, management controller 112, device(s) 116, temperature sensor 118, and heat-rejecting media 122, information handling system 102 may include one or more other information handling resources. In addition, for the sake of clarity and exposition of the present disclosure, FIG. 1 depicts only one air mover 108 and temperature sensor 118. In embodiments of the present disclosure, information handling system 102 may include any number of air movers 108 and temperature sensors 118.

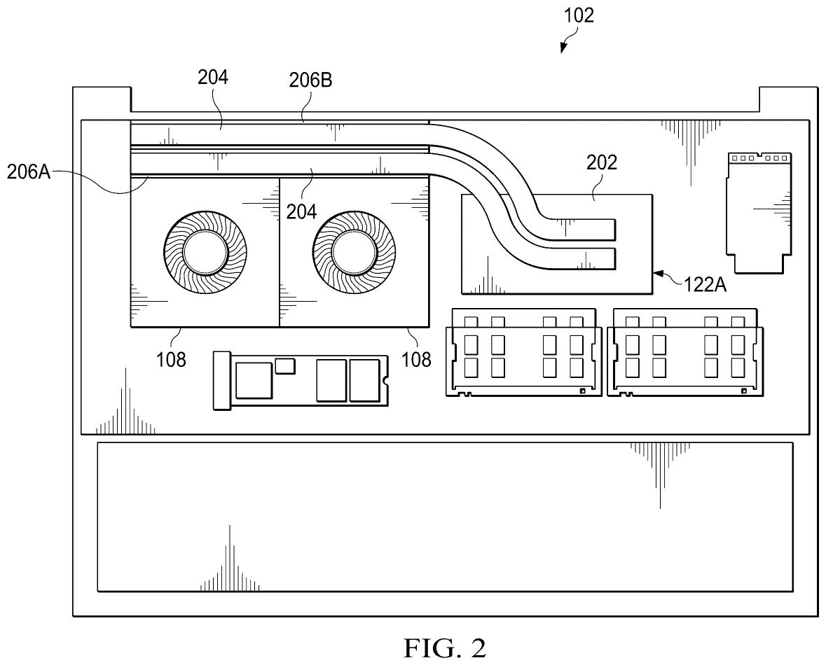

FIG. 2 illustrates a top-down plan view of selected components of information handling system 102, in accordance with embodiments of the present disclosure. As shown in FIG. 2, information handling system 102 may include heat-rejecting media 122A, which may be thermally coupled to a heat-generating component of information handling system 102. Such heat-generating component is not depicted in FIG. 2, as it may be obscured by heat-rejecting media 122A. Heat-rejecting media 122A depicted in FIG. 2 may be used to implement heat-rejecting media 122 depicted in FIG. 1.

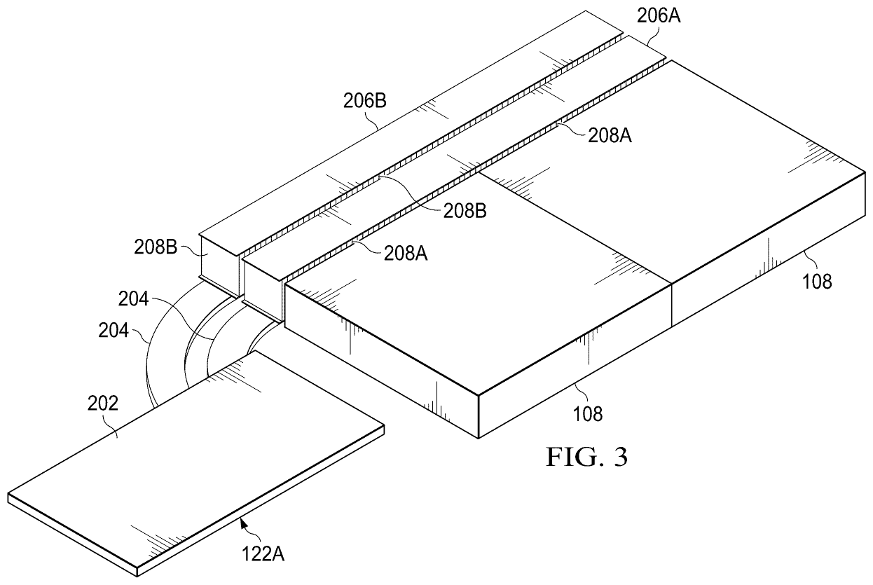

For additional clarity and exposition, FIG. 3 illustrates an isometric perspective view that isolates heat-rejecting media 122A and air movers 108, in accordance with embodiments of the present disclosure. While FIG. 2 depicts a “top” view of heat-rejecting media 122A and air movers 108, FIG. 3 (although in perspective view) predominantly depicts a “bottom” view of heat-rejecting media 122A and air movers 108 opposite to the view shown in FIG. 2.

As shown in FIGS. 2 and 3, heat-rejecting media 122A may include a heat spreader 202 which may thermally couple (e.g., either directly or via a thermal compound) to a heat-generating component of information handling system 102. Heat spreader 202 may receive heat generated by the heat-generating components, which heat may be further transferred to finstacks 206A and 206B (which may be referred to individually as finstack 206 and collectively as finstacks 206) via heat pipes 204 arranged between heat spreader 202 and finstacks 206.

As also shown in FIGS. 2 and 3, finstacks 206 may be arranged to be in fluid communication with air movers 108, such that airflow driven by air movers 108 may flow proximate to the surfaces of the plurality of fins 208A integral to finstack 206A and the plurality of fins 208B integral to finstack 206B, thus transferring heat from finstacks 206 to the airflow.

Each of heat spreader 202, heat pipes 204, and finstacks 206 (and their fins 208) may comprise materials with high thermal conductivity, such as metals. However, finstack 206A, and its fins 208A, may be formed using a material having a first thermal conductivity while finstack 206B, and its fins 208B, may be formed using a material having a second thermal conductivity substantially different from that of the first thermal conductivity. The finstack 206 having the higher thermal conductivity may depend on the direction of airflow driven by air movers 108, with the finstack 206 further upstream in the airflow having the higher thermal conductivity. In other words, should airflow be driven from air movers 108, through finstack 206A, then through finstack 206B, finstack 206A may have a substantially higher thermal conductivity. On the other hand, should airflow be drawn into finstack 206B, then into finstack 206A, then further through from air movers 108, finstack 206B may have a substantially higher thermal conductivity. As specific examples, in some embodiments, the upstream finstack 206 with higher thermal conductivity may comprise copper while the downstream finstack 206 with lower thermal conductivity may comprise aluminum.

Such an arrangement of finstacks 206 with substantially different thermal conductivities may be advantageous because (all things being equal) the airflow entrance of a finstack 206 may dissipate more heat than downstream portions of the finstack 206 due to the heat transfer coefficient of fins 208 being higher at the entrance to a finstack 206 as compared to the downstream portions of the fins 208. Thus, having higher heat transfer coefficients for fins 208 further upstream in a cooling airflow achieves a greater fin efficiency (i.e., a parameter representing the uniformity of fin temperature). Thus, the systems and methods described herein may sacrifice a portion of the thermal efficiency that would have been achieved if the entirety of both finstacks 208 were constructed from the higher thermally conductive material, while potentially minimizing weight and/or cost where the lower thermally conductive material is of lower density and/or costs than the higher thermally conductive material.

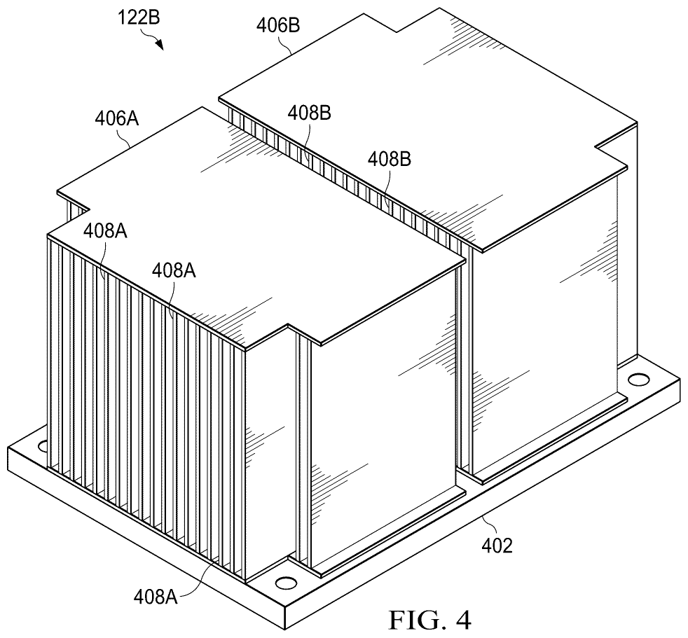

Such approach is not limited to form factors of heat-rejecting media 122A such as that shown in FIGS. 2 and 3, but may also apply to other types of heat-rejecting media. For example, FIG. 4 illustrates an isometric perspective view of example heat-rejecting media 122B implemented as a heatsink, in accordance with embodiments of the present disclosure. Heat-rejecting media 122B depicted in FIG. 4 may be used to implement heat-rejecting media 122 depicted in FIG. 1.

As shown in FIG. 4, heat-rejecting media 122B may include a heat spreader 402 which may thermally couple (e.g., either directly or via a thermal compound) to a heat-generating component of information handling system 102 (not explicitly shown in FIG. 4). Heat spreader 402 may receive heat generated by the heat-generating component, which heat may be further transferred to finstacks 406A and 406B (which may be referred to individually as finstack 406 and collectively as finstacks 406) thermally coupled to heat spreader 402. As shown in FIG. 4, finstack 406A may include a plurality of parallel fins 408A and finstack 406B may include a plurality of parallel fins 408B. Finstack 406A and finstack 406B may be arranged relative to one another and relative to air movers 108 (not explicitly shown in FIG. 4) such that airflow driven by air movers 108 flows through finstack 406A and proximate to fins 408A then flows through finstack 406B and proximate to fins 408B, thus transferring heat from fins 408 to the cooling airflow.

Each of heat spreader 402 and finstacks 406 (and their fins 408) may comprise materials with high thermal conductivity, such as metals. However, finstack 406A, and its fins 408A, may be formed using a material having a first thermal conductivity while finstack 406B, and its fins 408B, may be formed using a material having a second thermal conductivity substantially lower than that of the first thermal conductivity. As specific examples, in some embodiments, the upstream finstack 406A with the first thermal conductivity may comprise copper while the downstream finstack 406B with the second, lower thermal conductivity may comprise aluminum.

While copper and aluminum are used herein as examples for materials used in finstacks 206 and 406, any suitable materials, including metals and non-metals, differing substantially in thermal conductivity, may be used to achieve functionality and/or advantages identical or similar to those described above.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. §112(f) unless the words “means for” or “step for” are explicitly used in the particular claim.

What is claimed is:

1. An information handling system comprising:
an information handling resource;
an air mover configured to drive airflow within the information handling system; and
heat-rejecting media thermally coupled to the information handling resource and comprising:
a first portion configured to be located within the airflow and comprising a first thermally-conductive material having a first thermal conductivity; and
a second portion configured to be located within the airflow and comprising a second thermally-conductive material having a second thermal conductivity substantially different from the first thermal conductivity.

2. The information handling system of claim 1, wherein:
the first portion is upstream of the second portion with respect to the airflow; and
the first thermal conductivity is substantially higher than the second thermal conductivity.

3. The information handling system of claim 2, wherein:
the first thermally-conductive material is copper; and
the second thermally-conductive material is aluminum.

4. The information handling system of claim 1 wherein:
the first portion comprises a first finstack comprising a first plurality of fins; and
the second portion comprises a second finstack comprising a second plurality of fins.

5. The information handling system of claim 1, wherein the heat-rejecting media further comprises:
one or more heat pipes thermally coupled to the first portion and the second portion; and
a heat spreader thermally coupled to the information handling resource and thermally coupled to the first portion and the second portion via the one or more heat pipes.

6. The information handling system of claim 1, wherein the heat-rejecting media comprises a heatsink comprising the first portion and the second portion.

7. Heat-rejecting media configured to thermally couple to an information handling resource and comprising:
a first portion configured to be located within an airflow and comprising a first thermally-conductive material having a first thermal conductivity; and
a second portion configured to be located within the airflow and comprising a second thermally-conductive material having a second thermal conductivity substantially different from the first thermal conductivity.

8. The heat-rejecting media of claim 7, wherein:
the first portion is configured to be located upstream of the second portion with respect to the airflow; and
the first thermal conductivity is substantially higher than the second thermal conductivity.

9. The heat-rejecting media of claim 8, wherein:
the first thermally-conductive material is copper; and
the second thermally-conductive material is aluminum.

10. The heat-rejecting media of claim 8, wherein:
the first portion comprises a first finstack comprising a first plurality of fins; and
the second portion comprises a second finstack comprising a second plurality of fins.

11. The heat-rejecting media of claim 7, wherein the heat-rejecting media further comprises:
one or more heat pipes thermally coupled to the first portion and the second portion; and
a heat spreader thermally coupled to the information handling resource and thermally coupled to the first portion and the second portion via the one or more heat pipes.

12. The heat-rejecting media of claim 7, wherein the heat-rejecting media comprises a heatsink comprising the first portion and the second portion.

13. A method comprising:
configuring a first portion of heat-rejecting media within an airflow, wherein the first portion comprises a first thermally-conductive material having a first thermal conductivity, and wherein heat-rejecting media is configured to thermally couple to an information handling resource; and
configuring a second portion of the heat-rejecting media within the airflow, wherein the second portion comprises a second thermally-conductive material having a second thermal conductivity substantially different from the first thermal conductivity.

14. The method of claim 13, wherein:
the first thermal conductivity is substantially higher than the second thermal conductivity; and
the method further comprises configuring the first portion to be located upstream of the second portion with respect to the airflow.

15. The method of claim 14, wherein:
the first thermally-conductive material is copper; and
the second thermally-conductive material is aluminum.

16. The method of claim 13, wherein:
the first portion comprises a first finstack comprising a first plurality of fins; and
the second portion comprises a second finstack comprising a second plurality of fins.

17. The method of claim 13, further comprising, in order to form the heat-rejecting media:
thermally coupling one or more heat pipes to the first portion and the second portion; and
thermally coupling a heat spreader configured to thermally couple to the information handling resource to the first portion and the second portion via the one or more heat pipes.

18. The method of claim 13, wherein the heat-rejecting media comprises a heatsink comprising the first portion and the second portion.
